(19) United States
(12) Patent Application Publication
(10) Pub. No.: US 2025/0204000 A1
(43) Pub. Date: Jun. 19, 2025

(54) INTEGRATED CIRCUIT DEVICE WITH CO-METALIZED ELECTRICAL CONTACT

(71) Applicant: Intel Corporation, Santa Clara, CA (US)

(72) Inventors: Kan Zhang, HILLSBORO, OR (US); Chiao-Ti Huang, Portland, OR (US); Guowei Xu, Portland, OR (US); Saurabh Acharya, Beaverton, OR (US); Shengsi Liu, Portland, OR (US); Leonard P. Guler, Hillsboro, OR (US); Yang Zhang, Rio Rancho, NM (US); Tao Chu, Portland, OR (US); Robin Chao, Portland, OR (US); Ting-Hsiang Hung, Beaverton, OR (US); Feng Zhang, Hillsboro, OR (US); Chia-Ching Lin, Portland, OR (US); Anand S. Murthy, Portland, OR (US)

(73) Assignee: Intel Corporation, Santa Clara, CA (US)

(21) Appl. No.: 18/541,384

(22) Filed: Dec. 15, 2023

(51) Int. Cl. H01L 29/417; H01L 21/768; H01L 23/528

(52) U.S. Cl. CPC H10D 64/254; H01L 21/76802; H01L 21/76877; H01L 23/5286

(57) ABSTRACT

An IC device may include a support structure and a transistor built based on the support structure. The transistor may include an electrical contact over a semiconductor region in the transistor. The electrical contact may be a single structure formed by filling a single opening region with a conductive material. In an example, an end of the electrical contact may contact the semiconductor region, and another end of the electrical contact may contact a deep via. The deep via may extend through the support structure and contact a backside metal layer for delivering power or signal to the semiconductor region. In another example, an end of the electrical contact may contact the semiconductor region, and another end of the electrical contact may contact a semiconductor region in another transistor. A dielectric structure may be between the two semiconductor regions.

### BACKGROUND

Integrated circuit (IC) fabrication usually includes two stages. The first stage is referred to as the front end of line (FEOL). The second stage is referred to as the back end of line (BEOL). In the FEOL, individual components of semiconductor devices (e.g., transistor, capacitors, resistors, etc.) can be patterned on a wafer. For instance, the FEOL may include process steps for patterning electrical contacts (e.g., source electrode, drain electrode, and gate electrode) in transistors. In the BEOL, metal layers, vias, and insulating layers can be formed to get the individual components interconnected. The BEOL usually starts with forming the first metal layer on the wafer. The first metal layer is often called M0. More metal layers can be formed on top of M0, and these metal layers are often called M1, M2, and so on. Metal layers can be arranged at both the frontside and the backside of the semiconductor devices. One or more metal layers may be used for delivering power to the semiconductor devices.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an IC device including a FEOL section and a BEOL section, according to some embodiments of the disclosure.

FIG. 2 illustrates an IC device with co-metalized electrical contacts, according to some embodiments of the disclosure.

FIG. 3 illustrates another IC device with co-metalized electrical contacts, according to some embodiments of the disclosure.

FIGS. 4A-4D illustrate a process of fabricating an IC device with co-metalized electrical contacts, according to some embodiments of the disclosure.

FIGS. 5A-5C illustrate a process of fabricating another IC device with co-metalized electrical contacts, according to some embodiments of the disclosure.

FIGS. 6A and 6B illustrate a process of forming a source electrode and a drain electrode through co-metallization, according to some embodiments of the disclosure.

FIGS. 7A-7B are top views of a wafer and dies, according to some embodiments of the disclosure.

FIG. 8 is a side, cross-sectional view of an example IC package that may include one or more IC devices with co-metalized electrical contacts, according to some embodiments of the disclosure.

FIG. 9 is a cross-sectional side view of an IC device assembly that may include components having one or more IC devices with co-metalized electrical contacts, according to some embodiments of the disclosure.

FIG. 10 is a block diagram of an example computing device that may include one or more components with co-metalized electrical contacts, according to some embodiments of the disclosure.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

Currently available technologies enable scaling below 5 nanometers (or even below 3 nanometers) by delivering power on the backside of a die or wafer. Backside power delivery can eliminate the need to share interconnect resources between signal and power lines on the frontside. Instead, power delivery network is moved to the backside while signals can be carried by frontside interconnects. Backside power delivery can also enable cost savings as it can remove the need for a power delivery interconnect from lower metal layers at the frontside. It can also facilitate optimal fabrication of different metal layers. For instance, wider metal lines can be used for VDD and VSS, while thinner metal lines can be used for signal delivery. One of the approaches for backside power delivery is to have a via and a jumper transfer power from the backside power delivery network to transistor electrodes (e.g., source electrodes, drain electrodes, etc.). This approach can improve power delivery efficiency and increase area scaling.

Another approach for improving power delivery efficiency and increasing area scaling is connecting electrodes of neighboring transistors with a jumper. A good power delivery network can deliver constant and stable supply voltage to active circuits on the IC. It can be critical to have good contact between the transistor electrodes and jumpers to form a good power delivery network. Currently available approaches for forming transistors usually form transistor electrodes and jumps in separate metallization processes. For instance, a source or drain electrode may be formed first, while the jumper may be formed in a subsequent, separate deposition and polish process and connected to the source or drain electrode. Such approaches can produce an interface between the source or drain electrode and the jumper. The electrode-jumper interface can lead to high resistance and impact the performance of the device. Also, the presence of the electrode-jumper interface can introduce yield issues, such as electrode open, metal flake, and so on.

Embodiments of the present disclosure may improve on at least some of the challenges and issues described above by providing IC devices with co-metalized electrical contacts. An example co-metalized electrical contact may function as a combination of one or more traditional transistor electrodes and one or more traditional jumpers. The co-metalized electrical contact is a single conductive structure, which may be formed in a single deposition and polish process. The co-metallization can avoid formation of electrode-jumper interfaces. Also, it can avoid having a conductive structure on top of another conductive structure. Compared with currently available IC devices, IC devices with co-metalized electrical contacts can have lower electrode resistance, better power delivery efficiency, less risks of suffering from defects introduced at the electrode-jumper interface, and improved device performance.

In various embodiments of the present disclosure, an IC device may include a support structure and one or more transistors built based on the support structure. A transistor in the IC device may include one or more electrical contacts. An example electrical contact may be a conductive structure connected to a semiconductor region (e.g., a source region or drain region) of a transistor and coupling the semiconductor region to a power plane, ground plane, or signal plane. In an example, an end of the electrical contact is connected to the semiconductor region, and another end of the electrical contact is connected to a deep via. The deep via may extend through the support structure and contact a backside metal layer for delivering power or signal to the semiconductor region. In another example, an end of the electrical contact is connected to the semiconductor region, and another end of the electrical contact is connected to a semiconductor region in another transistor. A dielectric structure may be between the two semiconductor regions. The dielectric structure may be formed by forming a cut in a gate electrode and filling the cut with a dielectric material.

An electrical contact may be formed using a polymer structure for patterning. An opening region may be formed by removing one or more portions of the polymer structure. One or more other components of the IC device may also be partially or wholly removed to form the opening region with the right pattern. A conductive material may be deposited into the opening region. When excessive conductive material is deposited, the excessive conductive material may be removed, e.g., through polish. In some cases, multiple opening regions may be formed, and multiple electrical contacts may be formed in a single deposition and polish process. The electrical contacts may be separated by one or more electrical insulators.

It should be noted that, in some settings, the term “nanoribbon” has been used to describe an elongated semiconductor structure that has a substantially rectangular transverse cross-section (e.g., a cross-section in a plane perpendicular to the longitudinal axis of the structure), while the term “nanoribbon” has been used to describe a similar structure but with a substantially circular or square transverse cross-sections. In the following, a single term “nanoribbon” is used to describe an elongated semiconductor structure independent of the shape of the transverse cross-section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections.

In the following, some descriptions may refer to a particular source or drain (S/D) region or contact being either a source region/contact or a drain region/contact. However, unless specified otherwise, which region/contact of a transistor or diode is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a substrate that includes electrically conductive interconnect structures for providing electrical connectivity between different IC components. Metal layers described herein may also be referred to as “interconnect layers” to clearly indicate that these layers include electrically conductive interconnect structures which may, but do not have to be, metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−10%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−8% of a target value, e.g., within +/−5% of a target value or within +/−2% of a target value, based on the context of a particular value as described herein or as known in the art. Also, the term “or” refers to an inclusive “or” and not to an exclusive “or.”

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

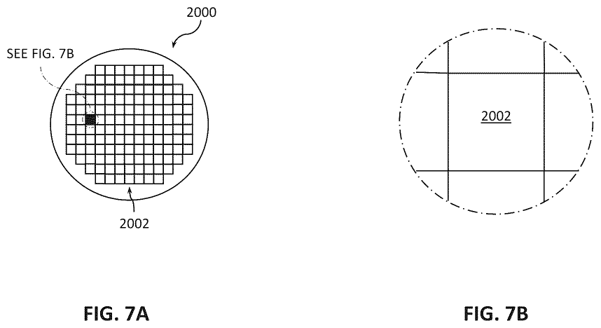

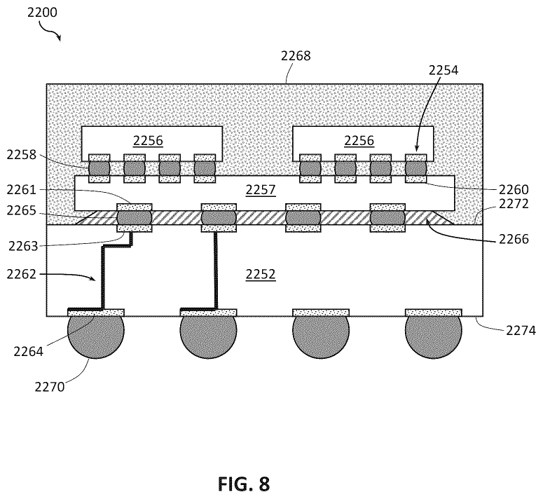

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 7A-7B, such a collection may be referred to herein without the letters, e.g., as “FIG. 8.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of semiconductor devices with co-metalized electrical contacts as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices with co-metalized electrical contacts as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

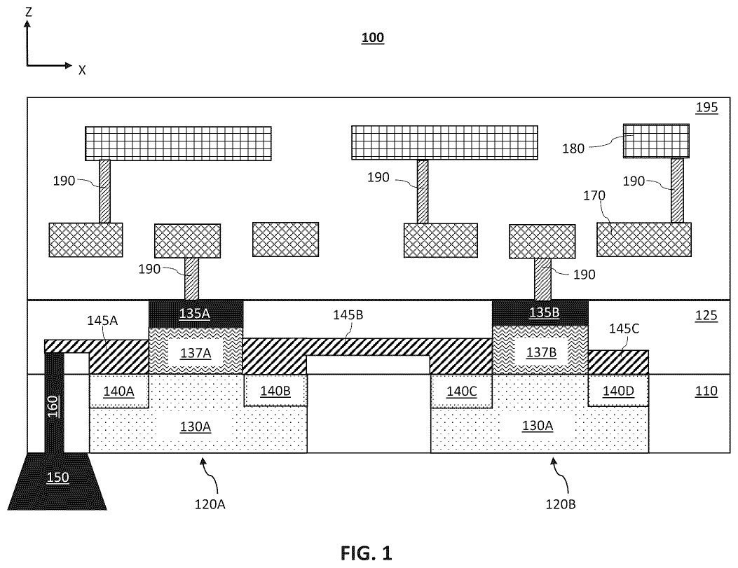

FIG. 1 illustrates an IC device 100 including a FEOL section and a BEOL section, according to some embodiments of the disclosure. The FEOL section includes components patterned and formed in FEOL. In the embodiments of FIG. 1, the FEOL section includes a support structure 110, transistors 120A and 120B (collectively referred to as “transistors 120” or “transistor 120”), and an electrical insulator 125. The BEOL section includes components patterned and formed in BEOL. In the embodiments of FIG. 1, the BEOL section includes a backside metal line 150, a deep via 160, frontside metal lines 170 (individually referred to as “frontside metal line 170”), frontside metal lines 180 (individually referred to as “frontside metal line 180”), vias 190 (individually referred to as “via 190”), and an electrical insulator 195.

In other embodiments, the FEOL section, the BEOL section, or the IC device 100 may include fewer, more, or different components. For example, the IC device 100 may include more transistors or other semiconductor devices not shown in FIG. 1. As another example, the IC device 100 may include a different number of deep vias, backside metal lines, frontside metal lines, vias, and so on. Also, the shapes, dimensions, and locations of the components of the IC device 100 shown in FIG. 1 are for illustration. The components of the IC device 100 may have different shapes, dimensions, or locations. Connections or electrical coupling between the components of the IC device 100 may also be different.

The support structure 110 may be any suitable structure, such as a substrate, a die, a wafer, or a chip, based on which the transistors 120 can be built. The support structure 110 may, e.g., be the wafer 2000 of FIG. 7A, discussed below, and may be, or be included in, a die, e.g., the singulated die 2002 of FIG. 7B, discussed below. In some embodiments, the support structure 110 may be a semiconductor substrate composed of semiconductor material systems including, for example, N-type or P-type materials systems, and, in some embodiments, the channel region 130, described herein, may be a part of the support structure 110. In some embodiments, the semiconductor substrate may be a crystalline substrate formed using a bulk silicon or a silicon-on-insulator substructure. In other embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of Group III-V, Group II-VI, or Group IV materials. In some embodiments, the substrate may be non-crystalline. In some embodiments, the support structure may be a printed circuit board (PCB) substrate. One or more transistors, such as the transistors 120 may be built on the support structure 110.

Although a few examples of materials from which the support structure 110 may be formed are described here, any material that may serve as a foundation upon which an IC may be built falls within the spirit and scope of the present disclosure. In various embodiments, the support structure 110 may include any such substrate, possibly with some layers and/or devices already formed thereon, not specifically shown in the present figures. As used herein, the term “support” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure 110 may provide material “support” in that, e.g., the IC devices/structures described herein are build based on the semiconductor materials of the support structure 110. However, in some embodiments, the support structure 110 may provide mechanical support.

A transistor 120 may be a field-effect transistor (FET), such as metal-oxide-semiconductor FET (MOSFET), tunnel FET (TFET), fin-based transistor (e.g., FinFET), nanoribbon-based FET, gate-all-around (GAA) FET, other types of FET, or some combination thereof. A transistor 120 includes semiconductor regions, such as a source region, a drain region, and a channel region between the source region and drain region. The semiconductor regions of the transistor 120 may be at least partially in the support structure 110. The support structure 110 may include a semiconductor material, from which at least a portion of the semiconductor structure is formed. One or more semiconductor regions of a transistor 120 may be a planar structure or a non-planar structure. A non-planar structure is a three-dimensional structure, such as fin or nanoribbon. A non-planar structure may have a longitudinal axis and a transvers cross-section perpendicular to the longitudinal axis. In some embodiments, a dimension of the non-planar structure along the longitudinal axis may be greater than dimensions along other directions, e.g., directions along axes perpendicular to the longitudinal axis. As shown in FIG. 1, the transistor 120A includes a channel region 130A and two semiconductor regions 140A and 140B functioning as the source and drain regions. The transistor 120B includes a channel region 130B and two semiconductor regions 140C and 140D functioning as the source and drain regions.

A channel region (e.g., the channel region 130A or 130B) includes one or more channel materials. A channel material may be composed of semiconductor material systems including, for example, N-type or P-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a compound semiconductor with a first sub-lattice of at least one element from Group III of the periodic table (e.g., Al, Ga, In), and a second sub-lattice of at least one element of group V of the periodic table (e.g., P, As, Sb). In some embodiments, the channel material may include a compound semiconductor with a first sub-lattice of at least one element from Group II of the periodic table (e.g., Zn, Cd, Hg), and a second sub-lattice of at least one element of Group IV of the periodic table (e.g., C, Si, Ge, Sn, Pb). In some embodiments, the channel material is an epitaxial semiconductor material deposited using an epitaxial deposition process. The epitaxial semiconductor material may have a polycrystalline structure with a grain size between about 2 nanometers and 100 nanometers, including all values and ranges therein.

For some example N-type transistor embodiments (i.e., for the embodiments where a transistor 120 is an NMOS (N-type metal-oxide-semiconductor) transistor or an N-type TFET), the channel material may advantageously include a Ill-V material having a high electron mobility, such as, but not limited to InGaAs, InP, InSb, and InAs. For some such embodiments, the channel material may be a ternary III-V alloy, such as InGaAs, GaAsSb, InAsP, or InPSb. For some InxGa1−xAs fin embodiments, In content (x) may be between 0.6 and 0.9, and may advantageously be at least 0.7 (e.g., In0.7Ga0.3As). In some embodiments with highest mobility, the channel material may be an intrinsic III-V material, i.e., a Ill-V semiconductor material not intentionally doped with any electrically active impurity. In alternate embodiments, a nominal impurity dopant level may be present within the channel material, for example to further fine-tune a threshold voltage Vt, or to provide HALO pocket implants, etc. Even for impurity-doped embodiments however, impurity dopant level within the channel material 304 may be relatively low, for example below 1015 dopant atoms per cubic centimeter (cm-3), and advantageously below 10¹³ cm⁻³. These materials may be amorphous or polycrystalline, e.g., having a crystal grain size between 0.5 nanometers and 100 nanometers.

For some example P-type transistor embodiments (i.e., for the embodiments where a transistor 120 is a PMOS (P-type metal-oxide-semiconductor) transistor or a P-type TFET), the channel material may advantageously be a Group IV material having a high hole mobility, such as, but not limited to Ge or a Ge-rich SiGe alloy. For some example embodiments, the channel material may have a Ge content between 0.6 and 0.9, and advantageously may be at least 0.7. In some embodiments with highest mobility, the channel material may be intrinsic III-V (or IV for P-type devices) material and not intentionally doped with any electrically active impurity. In alternate embodiments, one or more a nominal impurity dopant level may be present within the channel material, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 10¹³ cm⁻³. These materials may be amorphous or polycrystalline, e.g., having a crystal grain size between 0.5 nanometers and 100 nanometers.

In some embodiments, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, aluminium zinc oxide, or tungsten oxide. In general, for a thin-film transistor (TFT), the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminium gallium nitride, indium phosphite, black phosphorus, zinc sulfide, indium sulfide, gallium sulfide, each of which may possibly be doped with one or more of gallium, indium, aluminium, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front end components such as logic devices.

As noted above, the channel material may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors.

IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminium or nitrogen.

In some embodiments, the semiconductor region 140A and the semiconductor region 140B are connected to the channel region 130A, and the semiconductor region 140C and the semiconductor region 140D are connected to the channel region 130B. The semiconductor regions 140A-140D (collectively referred to as “semiconductor regions 140” or “semiconductor region 140”) may each include a semiconductor material with dopants. In some embodiments, the semiconductor region 140A and the semiconductor region 140B have the same semiconductor material, which may be the same as the channel material of the channel region 130A. Also, the semiconductor region 140C and the semiconductor region 140D have the same semiconductor material, which may be the same as the channel material of the channel region 130B. A semiconductor material of a semiconductor region 140 may be a Group IV material, a compound of Group IV materials, a Group III/V material, a compound of Group III/V materials, a Group II/VI material, a compound of Group II/VI materials, or other semiconductor materials. Example Group II materials include zinc (Zn), cadmium (Cd), and so on. Example Group III materials include aluminium (Al), boron (B), indium (In), gallium (Ga), and so on. Example Group IV materials include silicon (Si), germanium (Ge), carbon (C), etc. Example Group V materials include nitrogen (N), phosphorus (P), arsenic (As), antimony (Sb), and so on. Example Group VI materials include sulfur(S), selenium (Se), tellurium (Te), oxygen (O), and so on. A compound of Group IV materials can be a binary compound, such as SiC, SiGe, and so on. A compound of Group III/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

In some embodiments, the dopants in the semiconductor region 140A may be of the same type (e.g., N-type or P-type) as the dopants in the semiconductor region 140B, and the dopants in the semiconductor region 140C may be of the same type as the dopants in the semiconductor region 140D. The dopants of the semiconductor region 140A or 140B may be of an opposite type of the dopants in the semiconductor region 140C or 140D. In an example, the semiconductor region 140A or 140B has N-type dopants and the semiconductor region 140C or 140D has P-type dopants. In another example, the semiconductor region 140A or 140B has P-type dopants and the semiconductor region 140C or 140D has N-type dopants. In other embodiments, the four semiconductor regions 140 may have the same type of dopants. Example N-type dopants include Te, S, As, tin (Sn), Si, Ga, Se, S, In, Al, Cd, chlorine (Cl), iodine (I), fluorine (F), and so on. Example P-type dopants include beryllium (Be), Zn, magnesium (Mg), Sn, P, Te, lithium (Li), sodium (Na), Ga, Cd, and so on.

In some embodiments, a semiconductor region 140 may be highly doped, e.g., with dopant concentrations of about 1·10²¹ cm⁻³, in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the semiconductor regions 140 may be the regions having dopant concentration higher than in other regions, e.g., higher than a dopant concentration in the channel region 130A or 130B, and, therefore, may be referred to as “highly doped” (HD) regions.

The channel region 130A or 130B may include one or more semiconductor materials with a doping concentration significantly smaller than that of a semiconductor region 140. For example, in some embodiments, the channel material of the channel region 130A or 130B may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material is still significantly lower than the dopant level in the semiconductor region 140, for example below 10¹⁵ cm⁻³ or below 10¹³ cm⁻³. Depending on the context, the term “S/D terminal” may refer to an S/D region or a S/D contact or electrode of a transistor.

A transistor 120 also includes electrical contacts over the semiconductor regions. An electric contact is a conductive structure that includes one or more conductive materials, such as metal (e.g., ruthenium, palladium, platinum, cobalt, nickel, etc.), conductive metal oxides (e.g., ruthenium oxide, etc.), other types of conductive materials, or some combination thereof. An electric contact may have an end contacting the corresponding semiconductor region. An electrical contact over a source region is referred to as a source contact or source electrode. An electrical contact over a drain region is referred to as a drain contact or drain electrode. An electrical contact over a channel region is referred to as a gate contact or gate electrode. As shown in FIG. 1, the transistor 120A includes a gate electrode 135A and a gate insulator 137A over the channel region 130A. The gate electrode 135A and a gate insulator 137A may constitute the gate of the transistor 120A. In some embodiments, the gate may wrap around at least a portion of the channel region 130A. The transistor 120B includes a gate electrode 135B and a gate insulator 137B over the channel region 130B. The gate electrode 135B and a gate insulator 137B may constitute the gate of the transistor 120B. In some embodiments, the gate may wrap around at least a portion of the channel region 130B.

The gate electrode 135A or 135B may be coupled to a gate terminal that controls gate voltages applied on the transistor 120. The gate electrode 135A or 135B may include one or more gate electrode materials, where the choice of the gate electrode materials may depend on whether the transistor 120 is a P-type transistor or an N-type transistor. For a P-type transistor, gate electrode materials that may be used in different portions of the gate electrode may include, but are not limited to, Ru, Pd, Pt, Co, Ni, and conductive metal oxides (e.g., ruthenium oxide). For an N-type transistor, gate electrode materials that may be used in different portions of the gate electrode, but are not limited to, hafnium, zirconium, titanium, tantalum, aluminium, alloys of these metals, and carbides of these metals (e.g., hafnium carbide, zirconium carbide, titanium carbide, tantalum carbide, and aluminium carbide). In some embodiments, the gate electrode 135A or 135B may include a stack of a plurality of gate electrode materials, where zero or more materials of the stack are workfunction (WF) materials and at least one material of the stack is a fill metal layer. Further materials/layers may be included next to the gate electrode for other purposes, such as to act as a diffusion barrier layer or/and an adhesion layer.

The gate insulator 137A or 137B separates at least a portion of the channel region 130A or 130B from the gate electrode 135A or 135B so that the channel region 130A or 130B is insulated from the gate electrode 135A or 135B. In some embodiments, the gate insulator 137A or 137B may wrap around at least a portion of the channel region 130A or 130B. The gate insulator 137A or 137B may also wrap around at least a portion of the semiconductor region 140A or 140C or the semiconductor region 140B or 140B. At least a portion of the gate insulator 137A or 137B may be wrapped around by the gate electrode 135A or 135B. The gate insulator 137A or 137B includes an electrical insulator, such as a dielectric material, hysteretic material, and so on. Example dielectric material includes oxide (e.g., Si based oxides, metal oxides, etc.), nitride (e.g., silicon nitride, etc.), carbide, and so on. Example hysteretic material include ferroelectric materials, antiferroelectric materials, etc.

The two transistors 120 also includes electrical contacts 145A, 145B, and 145C. The electrical contacts 145A and 145B may be formed through co-metallization. In some embodiments, some or all of the two gate electrodes 135A and 135B and the three electrical contacts 145A, 145B, and 145C may be co-metallized. In some embodiments, the electrical contact 145A is a single conductive structure. There may be no interface in the electrical contact 145A. The electrical contact 145A contacts the semiconductor region 140A and the deep via 160. The electrical contact 145B may also be a single conductive structure that is connected to the semiconductor region 140B in the transistor 120A and to the semiconductor region 140C in the transistor 120B. The electrical contact 145B can make the semiconductor region 140B and 140C be at the same electrical potential during the operation of the IC device. Different from conventional electrical contacts in transistors that has at least two metal pieces for coupling a source or drain region to a deep via, the single-piece design of the electrical contacts 145A and 145B can reduce resistance and improve the efficiency of power or signal delivery. Even though not shown in FIG. 1, the electrical contact 145C may also be a single conductive structure that is connected to the semiconductor region 140D and a deep via for delivering power or signal to the semiconductor region 140D.

In the embodiments of FIG. 1, the transistors 120A may receive power from a backside power delivery network that includes the backside metal line 150. The backside metal line 150 is connected to the deep via 160. The backside metal line 150 and the deep via 160 may each include one or more conductive materials, such as the conductive materials described above. The backside metal line 150 may also be referred to as backside interconnect or power interconnect. The deep via 160 may be referred to as a power via. In some embodiments, the backside metal line 150 may be a power plane of the IC device 100. The backside metal line 150 may be, or may be coupled to, a VDD terminal. In some embodiments, the backside metal line 150 may facilitate delivery of a positive supply voltage to the electrical contact 145A, versus the electrical contact 145B may receive a negative supply voltage or may be coupled to a ground plane. The transistor 120 may be an N-type transistor, e.g., a NMOS. In other embodiments, the backside metal line 150 may facilitate delivery of a negative supply voltage to the electrical contact 145A or couple the electrical contact 145A to ground. The transistor may be a P-type transistor, e.g., a PMOS transistor.

As shown in FIG. 1, the deep via 160 extends from the backside of the support structure 110 towards the frontside of the support structure 110. In some embodiments, the deep via 160 has a longitudinal axis along the Z axis. The widths of various portions of the deep via 160 along the X axis may be the same or substantially similar. In some embodiments, a width of the deep via 160 along the X axis is in a range from approximately 10 nanometers to approximately 20 nanometers. The deep via 160 may penetrate at least part of the support structure 110. In some embodiments, the deep via 160 may penetrate the whole support structure 110 along the Z axis. The deep via 160 may be a through-silicon-via (TSV). Each of the electrical contacts 145A, 145B, and 145C, gate electrodes 135A and 135B, and deep via 160 may be at least partially surrounded by the electrical insulator 125 to avoid undesirable electrical connection or coupling. The electrical insulator 125 may include an electrical insulator, such as a dielectric material, hysteretic material, and so on.

The frontside metal lines 170 and 180 are stacked over the support structure 110, the transistors 120, and the electrical insulator 125 along the Z axis. Some frontside metal lines 170 are coupled to the gate electrodes 135A and 135B through vias 190. In some embodiments, the frontside metal lines 170 may be used to deliver signals (e.g., control signals) to the gate electrodes 135A and 135B. Some other frontside metal lines 170 are coupled to the frontside metal lines 180 through some other vias 190. In other embodiments, the electrical connections of the frontside metal lines 170 and 180 may be different. Even though not shown in FIG. 1, the frontside metal line 170 or 180 may be coupled with other devices than the transistor 120, such as diodes, power sources, resistors, capacitors, inductors, sensors, transceivers, receivers, antennas.

In some embodiments, the frontside metal lines 170 may constitute the metal layer that is arranged closest to the transistors 120 and may be the first BEOL layer at the frontside of the support structure 110. In some embodiments, the metal layer may be referred to as M0. The frontside metal lines 180 may constitute the second metal layer at the frontside, which may be referred to as M1. There may be one or more metal layers that are arranged on top of the frontside metal lines 170, which may be referred to as M3, M4, and so on. The frontside metal lines 170 and 180 are at least partially surrounded by the electrical insulator 195. The electrical insulator 195 may include one or more electrically insulating materials, such as a dielectric material, hysteretic material, and so on.

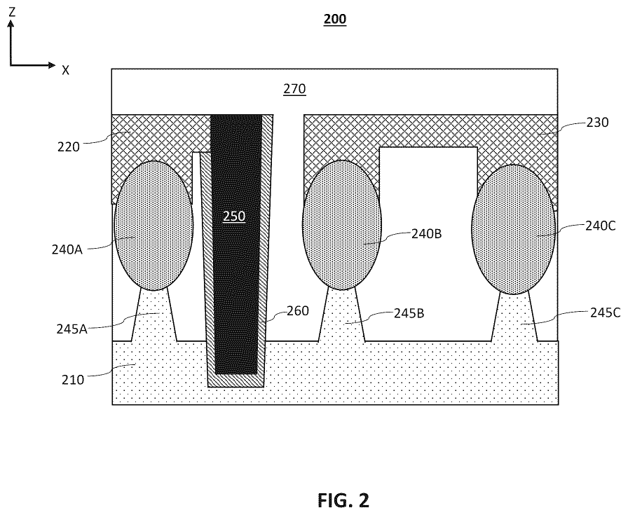

FIG. 2 illustrates an IC device 200 with co-metalized electrical contacts 220 and 230, according to some embodiments of the disclosure. The IC device 100 in FIG. 1 may be an example of the IC device 200. The IC device 200 also includes a substrate 210, semiconductor structures 240A-240C (collectively referred to as “semiconductor structures 240” or “semiconductor structure 240”), semiconductor structures 245A-245C (collectively referred to as “semiconductor structures 245” or “semiconductor structure 245”), a conductive structure 250, a dielectric layer 260, and electrical insulator 270. For the purpose of illustration, some components of the IC device 200 are not shown in FIG. 2. The IC device 200 may be used as a logic device or part of a logic device.

The semiconductor structures 240 may be used as source regions or drain regions of transistors. In an example, the semiconductor structure 240A may be a source region of a transistor, the semiconductor structure 240B may be a drain region of the transistor, and the semiconductor structure 240C may be a drain region of another transistor. In another example, the semiconductor structure 240A may be a drain region of a transistor, the semiconductor structure 240B may be a source region of the transistor, and the semiconductor structure 240C may be a source region of another transistor. In some embodiments, the semiconductor structures 240 may have crystal structures. A semiconductor structure 240 may be formed through an epitaxial growth process, in which a crystal material may be formed with one or more well-defined orientations with respect to a crystal substrate after the material is deposited onto the crystal substrate. The semiconductor structures 240 may also be referred to as epitaxial structures or epitaxial semiconductor structures. The crystal substrate used for epitaxial growth may be a die or wafer. The crystal direction of the epitaxial structures may be determined based on a crystal direction in the crystal substrate.

The semiconductor structures 245 may each be connected to a corresponding semiconductor structure 240. A semiconductor structure 245 may be a sub-fin. In some embodiments, the semiconductor structure 245 may have the same semiconductor material(s) as the corresponding semiconductor structure 240. The semiconductor structures 245 are also connected to the substrate 210. An example of the substrate 210 is the support structure 110 in FIG. 1. The substrate 210 is at least partially penetrated by the conductive structure 250. The conductive structure 250 may be a via, e.g., a TSV. The conductive structure 250 may have a longitudinal axis along the Z axis. The conductive structure 250 is wrapped around by the dielectric layer 260. The dielectric layer 260 includes a dielectric material, such as the dielectric materials described above.

The co-metalized electrical contact 220 has an end connected to the semiconductor structure 240A and another end connected to the conductive structure 250. The end connected to the conductive structure 250 is over a portion of the dielectric layer 260 in a direction along the Z axis and is over another portion of the dielectric layer 260 in a direction along the X axis. The conductive structure 250 may be connected to a metal layer at the backside of the substrate 210, while the semiconductor structures 240 are at the frontside of the substrate 210. The backside metal layer may function as a power plane, ground plane, or signal plane of the IC device 200. The co-metalized electrical contact 220, the conductive structure 250, and the metal layer may constitute a power or signal delivery network.

The co-metalized electrical contact 230 has an end connected to the semiconductor structure 240B and another end connected to the semiconductor structure 240C. The semiconductor structures 240B and 240C may be shorted by the co-metalized electrical contact 230. Even though not shown in FIG. 2, the co-metalized electrical contact 230 may be coupled to a metal layer which may function as a power plane, ground plane, or signal plane of the IC device 200.

The co-metalized electrical contacts 220 and 230 are formed through co-metallization. For instance, two opening regions may be patterned, e.g., after the semiconductor structures 240, the conductive structure 250, and the dielectric layer 260 are formed. One of the opening regions may have the shape and size of the co-metalized electrical contact 220, and the other opening region may have the shape and size of the co-metalized electrical contact 230. Each opening region may be formed in one or more steps. The co-metalized electrical contact 220 may be formed by filling the first opening region with a conductive material. The co-metalized electrical contact 230 may be formed by filling the second opening region with the same conductive material or a different conductive material. An example conductive material may be metal, such as tungsten. In some embodiments, the co-metalized electrical contacts 220 and 230 may be formed together by providing (e.g., depositing) a conductive material into the two opening regions at the same time. Given the co-metallization process(es), the co-metalized electrical contact 220 is a single, continuous piece that has no interface inside. The co-metalized electrical contact 230 is also a single, continuous piece that has no interface inside.

The electrical insulator 270 separate other components in the IC device 200 to insulate them from each other. For instance, the electrical insulator 270 separates the co-metalized electrical contact 220 and the conductive structure 250 from the co-metalized electrical contact 230. Also, the semiconductor structures 240 and 245 are surrounded by the electrical insulator 270. The electrical insulator 270 may include one or more electrically insulating materials, such as the ones described above. At least part of the electrical insulator 270 may be formed after the co-metalized electrical contacts 220 and 230 are formed.

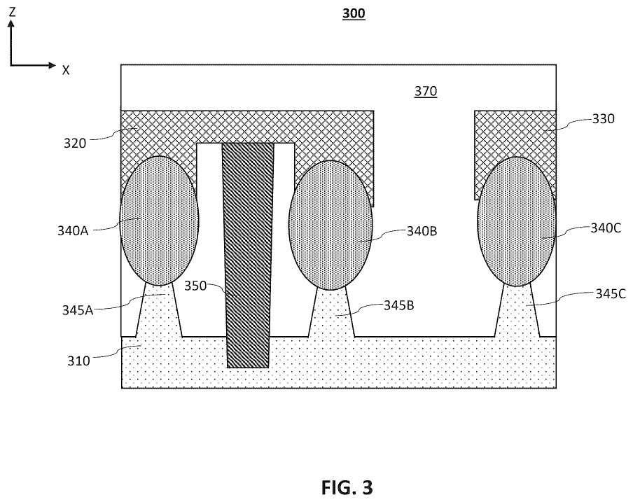

FIG. 3 illustrates another IC device 300 with co-metalized electrical contacts 320 and 330, according to some embodiments of the disclosure. The IC device 300 also includes a substrate 310, semiconductor structures 340A-340C (collectively referred to as “semiconductor structures 340” or “semiconductor structure 340”), semiconductor structures 345A-345C (collectively referred to as “semiconductor structures 345” or “semiconductor structure 345”), a dielectric structure 350, and electrical insulator 370. For the purpose of illustration, some components of the IC device 300 are not shown in FIG. 3. The IC device 300 may be used as a memory device (e.g., a SRMA, DRAM, etc.) or part of a memory device.

The semiconductor structures 340 may be used as source regions or drain regions of transistors. In an example, the semiconductor structure 340A may be a source region of a first transistor, the semiconductor structure 340B may be a source region of a second transistor, and the semiconductor structure 340C may be a drain region of the second transistor. In another example, the semiconductor structure 340A may be a drain region of a first transistor, the semiconductor structure 340B may be a drain region of a second transistor, and the semiconductor structure 340C may be a source region of the second transistor. In some embodiments, the semiconductor structures 340 may have crystal structures. A semiconductor structure 340 may be formed through an epitaxial growth process, in which a crystal material may be formed with one or more well-defined orientations with respect to a crystal substrate after the material is deposited onto the crystal substrate. The semiconductor structures 340 may also be referred to as epitaxial structures or epitaxial semiconductor structures. The crystal substrate used for epitaxial growth may be a die or wafer. The crystal direction of the epitaxial structures may be determined based on a crystal direction in the crystal substrate.

The semiconductor structures 345 may each be connected to a corresponding semiconductor structure 340. A semiconductor structure 345 may be a sub-fin. In some embodiments, the semiconductor structure 345 may have the same semiconductor material(s) as the corresponding semiconductor structure 340. The semiconductor structures 345 are also connected to the substrate 310. An example of the substrate 310 is the support structure 110 in FIG. 1.

The co-metalized electrical contact 320 has an end connected to the semiconductor structure 340A and another end connected to the semiconductor structure 340B. The co-metalized electrical contact 320 may function as the source contact or drain contact of the two transistors. The co-metalized electrical contact 330 has an end connected to the semiconductor structure 340C. The co-metalized electrical contact 330 may function as the drain contact or source contact of the second transistor. Even though not shown in FIG. 3, the co-metalized electrical contact 320 or 330 may be coupled to a metal layer which may function as a power plane, ground plane, or signal plane of the IC device 300. The co-metalized electrical contacts 320 and 330 are formed through co-metallization. For instance, two opening regions may be patterned, e.g., after the semiconductor structures 340 and the dielectric structure 350 are formed. One of the opening regions may have the shape and size of the co-metalized electrical contact 320, and the other opening region may have the shape and size of the co-metalized electrical contact 330. Each opening region may be formed in one or more steps. The co-metalized electrical contact 320 may be formed by filling the first opening region with a conductive material. The co-metalized electrical contact 330 may be formed by filling the second opening region with the same conductive material or a different conductive material. An example conductive material may be metal, such as tungsten. In some embodiments, the co-metalized electrical contacts 320 and 330 may be formed together by providing (e.g., depositing) a conductive material into the two opening regions at the same time. Given the co-metallization process(es), the co-metalized electrical contact 320 is a single, continuous piece that has no interface inside. The co-metalized electrical contact 330 is also a single, continuous piece that has no interface inside.

The dielectric structure 350 is between the semiconductor structures 340A and 340B along the X axis. The dielectric structure 350 may isolate the transistor including the semiconductor structure 340A from the transistor including the semiconductor structure 340B. In some embodiments, the dielectric structure 350 is formed by removing a gate electrode to form an opening region and filling the opening region with a dielectric material. The dielectric material may be one of the dielectric materials described above. Even though not shown in FIG. 3, the IC device 300 may include a gate electrode between the semiconductor structure 340B and the semiconductor structure 340C. The gate electrode may be over a channel region of the transistor including the semiconductor structure 340B and the semiconductor structure 340C. In some embodiments, the gate electrode may be parallel to the dielectric structure 350. For instance, the gate electrode and the dielectric structure 350 may each have a longitudinal axis along the Z axis.

The electrical insulator 370 separate other components in the IC device 300 to insulate them from each other. For instance, the electrical insulator 370 separates the co-metalized electrical contact 320 from the co-metalized electrical contact 330. Also, the semiconductor structures 340 and 345 are surrounded by the electrical insulator 370. The electrical insulator 370 may include one or more electrically insulating materials, such as the ones described above. At least part of the electrical insulator 370 may be formed after the co-metalized electrical contacts 320 and 330 are formed.

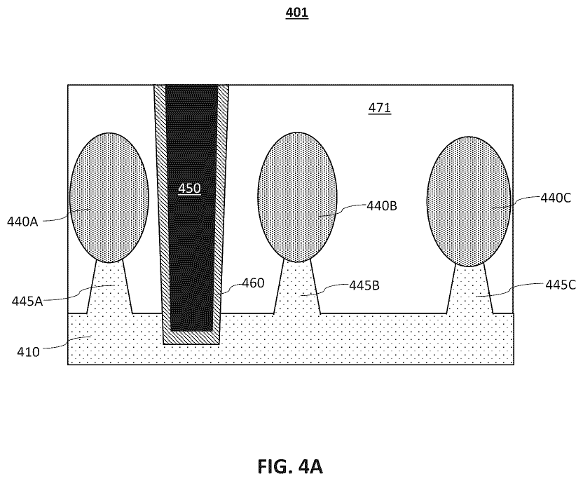

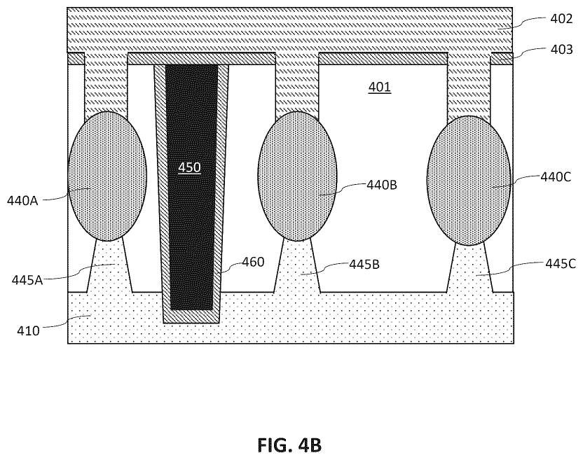

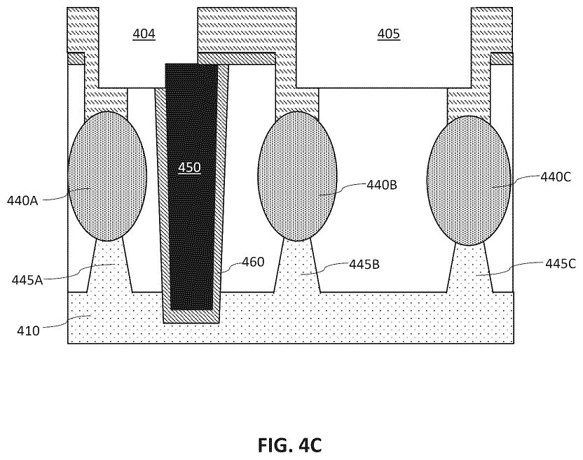

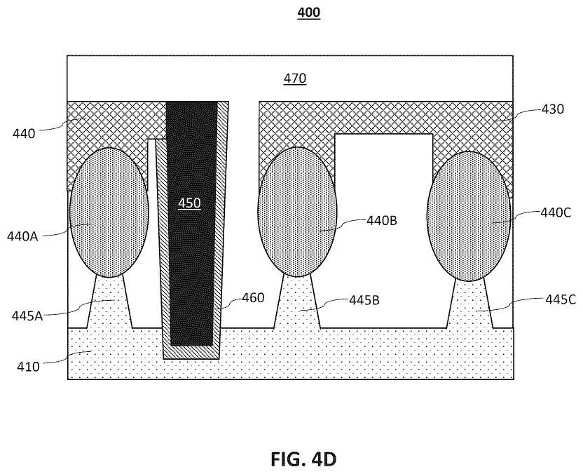

FIGS. 4A-4D illustrate a process of fabricating an IC device 400 with co-metalized electrical contacts 420 and 430, according to some embodiments of the disclosure. The IC device 400 may be an example of the IC device 200 in FIG. 2. Although the process is described with reference to the steps shown in FIGS. 4A-4D, many other processes for fabricating IC devices with co-metalized electrical contacts may alternatively be used. For example, the order of execution of the steps shown in FIGS. 4A-4D may be changed. As another example, some of the steps may be changed, eliminated, or combined. For the purpose of illustration, some components of the IC device 400 are not shown in FIGS. 4A-4D.

FIG. 4A shows a device 401 that includes a substrate 410, semiconductor structures 440A-440C (collectively referred to as “semiconductor structures 440” or “semiconductor structure 440”), semiconductor structures 445A-445C (collectively referred to as “semiconductor structures 445” or “semiconductor structure 445”), a conductive structure 450, a dielectric layer 460, and electrical insulator 471. The substrate 410 may be a semiconductor substrate. An example of the substrate 410 is the support structure 110 in FIG. 1. The substrate 410 may facilitate formation of the semiconductor structures 440 or 445. The semiconductor structures 440 may be used as source regions or drain regions of transistors. The semiconductor structures 445 may each be connected to a corresponding semiconductor structure 440. A semiconductor structure 445 may be a sub-fin. In some embodiments, the semiconductor structure 445 may have the same semiconductor material(s) as the corresponding semiconductor structure 440. The semiconductor structures 445 are also connected to the substrate 410. The conductive structure 450 may be a via, e.g., a TSV. The conductive structure 450 may have a longitudinal axis along the Z axis. The conductive structure 450 is wrapped around by the dielectric layer 460. The dielectric layer 460 includes a dielectric material, such as the dielectric materials described above. The electrical insulator 471 may include one or more electrically insulating materials, such as the electrically insulating materials described above. In some embodiments, some or all the components shown in FIG. 4A may be formed in FEOL.

In FIG. 4B, a polymer structure 402 is formed. A dielectric layer 403 is also formed. The polymer structure 402 and dielectric layer 403 may be used for patterning purposes. The polymer structure 402 has a portion connected to the semiconductor structure 440A, another portion connected to the semiconductor structure 440B, and yet another portion connected to the semiconductor structure 440C. The remaining portions of the polymer structure 402 are over the electrical insulator 471 with the dielectric layer 403 being arranged between. The polymer structure 402 may be formed by removing certain portions of the electrical insulator 471 (e.g., the portions that are over the semiconductor structures 440) to form openings and depositing a polymeric material onto a surface of the device 401 after the openings are formed. The dielectric layer 403 includes a dielectric material, such as silicon nitride. In some embodiments, the dielectric layer 403 may include the same material as the dielectric layer 460. In some embodiments, the dielectric layer 403 may be used as a hard mask.

In FIG. 4C, various portions of the polymer structure 402 and the dielectric layer 403 are removed. Also, a portion of the dielectric layer 460 is removed. Two opening regions 404 and 405 are formed.

In FIG. 4D, the remaining portions of the polymer structure 402 and the dielectric layer 403 are removed. The opening regions 404 and 405 are expanded. The co-metalized electrical contacts 420 and 430 are formed by filling the expanded opening regions with a metal, e.g., tungsten. The co-metalized electrical contact 420 is connected to the semiconductor structure 440A and the conductive structure 450. The co-metalized electrical contact 420 is connected to the semiconductor structure 440B and the semiconductor structure 440C. The co-metalized electrical contacts 420 and 430 may be formed in a single metal deposition process. In some embodiments, excessive metal may be deposited. Such excessive metal may be removed after the deposition process, e.g., through a polish process, to form the co-metalized electrical contacts 420 and 430. After the co-metalized electrical contacts 420 and 430 are formed, more electrical insulator is added to form an electrical insulator 470. For instance, one or more electrically insulating materials may be deposited onto top surfaces of the co-metalized electrical contacts 420 and 430, the existing electrical insulator, the conductive structure 450, and the dielectric layer 460. The process shown in FIGS. 4A-4D may be part of a FEOL. Frontside or backside metal layers may be formed in a BEOL after the FEOL.

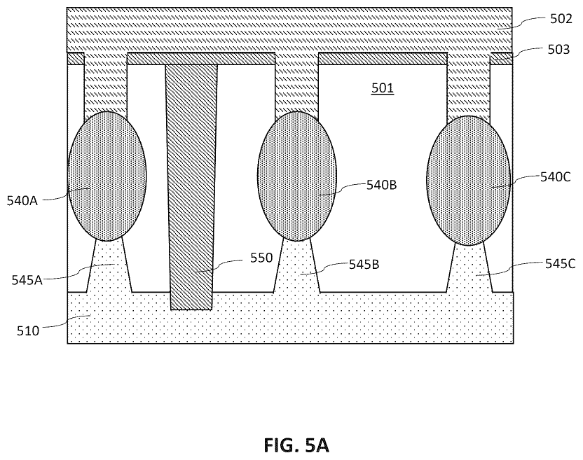

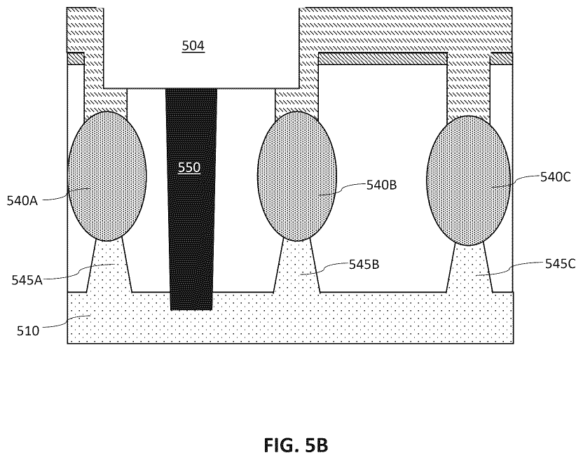

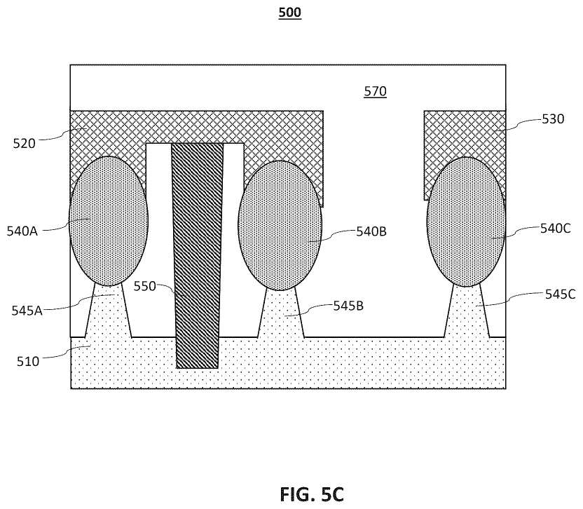

FIGS. 5A-5C illustrate a process of fabricating another IC device with co-metalized electrical contact, according to some embodiments of the disclosure. The IC device 500 may be an example of the IC device 300 in FIG. 3. Although the process is described with reference to the steps shown in FIGS. 5A-5C, many other processes for fabricating IC devices with co-metalized electrical contacts may alternatively be used. For example, the order of execution of the steps shown in FIGS. 5A-5C may be changed. As another example, some of the steps may be changed, eliminated, or combined. For the purpose of illustration, some components of the IC device 500 are not shown in FIGS. 5A-5C.

FIG. 5A shows a substrate 510, semiconductor structures 540A-540C (collectively referred to as “semiconductor structures 540” or “semiconductor structure 540”), semiconductor structures 545A-545C (collectively referred to as “semiconductor structures 545” or “semiconductor structure 545”), a dielectric structure 550, an electrical insulator 501, a polymer structure 502, and a dielectric layer 503. The substrate 510 may be a semiconductor substrate. An example of the substrate 510 is the support structure 110 in FIG. 1. The substrate 510 may facilitate formation of the semiconductor structures 540 or 545. The semiconductor structures 540 may be used as source regions or drain regions of transistors. The semiconductor structures 545 may each be connected to a corresponding semiconductor structure 540. A semiconductor structure 545 may be a sub-fin. In some embodiments, the semiconductor structure 545 may have the same semiconductor material(s) as the corresponding semiconductor structure 540. The semiconductor structures 545 are also connected to the substrate 510. The dielectric structure 550 is between the semiconductor structure 540A and the semiconductor structure 540B. The dielectric structure 550 may have the same dielectric material (e.g., silicon nitride, etc.) as the dielectric layer 503. The polymer structure 502 may be formed by depositing a polymer material onto the top surface.

In FIG. 5B, an opening region 504 is formed by removing various portions of the polymer structure 502, the dielectric layer 503, and the dielectric structure 550. This step may be a step for patterning a jumper.

In FIG. 5C, the remaining portions of the polymer structure 502 and the dielectric layer 503 are removed. The opening region 504 is expanded, and another opening region is formed over the semiconductor structure 540C. The co-metalized electrical contacts 520 and 530 are formed by filling these opening regions with a metal, e.g., tungsten. The co-metalized electrical contact 520 is connected to the semiconductor structure 540A and the semiconductor structure 540B. The co-metalized electrical contact 520 is connected to the semiconductor structure 540C. The co-metalized electrical contacts 520 and 530 may be formed in a single metal deposition process. In some embodiments, excessive metal may be deposited. Such excessive metal may be removed after the deposition process, e.g., through a polish process, to form the co-metalized electrical contacts 520 and 530. After the co-metalized electrical contacts 520 and 530 are formed, more electrical insulator is added to form an electrical insulator 570. For instance, one or more electrically insulating materials may be deposited onto top surfaces of the co-metalized electrical contacts 520 and 530, the existing electrical insulator, the dielectric structure 550, and the dielectric layer 560. The process shown in FIGS. 5A-5C may be part of a FEOL. Frontside or backside metal layers may be formed in a BEOL after the FEOL.

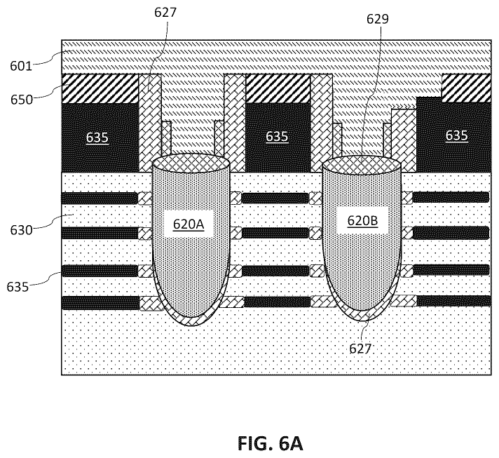

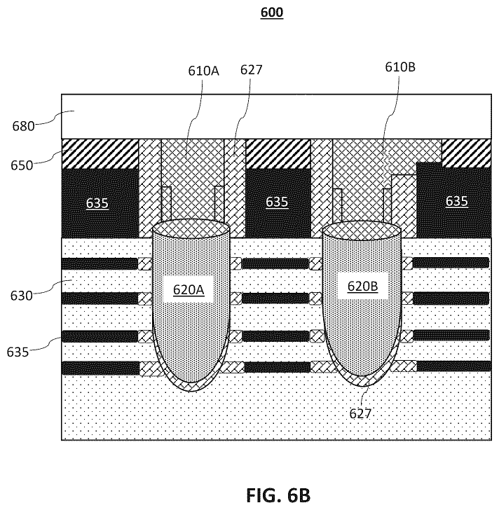

FIGS. 6A and 6B illustrate a process of forming a source electrode 610A and a drain electrode 610B in an IC device 600 through co-metallization, according to some embodiments of the disclosure. The IC device 600 may be an example of the IC device 300 in FIG. 3 or the IC device 500 in FIG. 5C. The IC device 600 may be used as a memory device (e.g., a SRMA, DRAM, etc.) or part of a memory device.

FIG. 6A shows a source region 620A, a drain region 620B, dielectric structures 627 (individually referred to as “dielectric structure 627”), conductive structures 629 (individually referred to as “conductive structure 629”), semiconductor structures 630 (individually referred to as “semiconductor structure 630”), gate electrodes 635 (individually referred to as “electrode 135”), spacers 650 (individually referred to as “spacer 650”), and a polymer structure 601. In some embodiments, the semiconductor structures 630 have a non-planar shape. For instance, the semiconductor structures 630 may be nanoribbons. The portions of the semiconductor structures 630 between the source region 620A and drain region 620B may constitute a channel region. The dielectric structures 627 may separate the source region 620A and drain region 620B from the gate electrodes 635. In some embodiments, the dielectric structures 627 include one or more high-k dielectric materials. A high-k dielectric material may have a dielectric constant that is higher than the dielectric constant of silicon dioxide, which may be approximately 3.9. Examples of high-k dielectric materials include aluminium oxide, zirconium dioxide, hafnium (IV) oxide, silicon nitride, tantalum pentoxide, lead zirconate titanate, and so on.

The spacers 650 are electrically insulative and may include one or more electrical insulating materials, such as the ones described above. The spacers 650 may separate components in the IC device 600 from each other so that these components are not undesirably coupled to each other. For instance, the spacers 650 may separate some or all the gate electrodes 635 from the source region 620A and the drain region 620B. In some embodiments, a spacer 650 may include a dielectric material that is different from the dielectric material(s) in the dielectric structures 627. In an example, a spacer 650 may include one or more low-k dielectric materials. A low-k dielectric material may have dielectric constants lower than the dielectric constant of silicon dioxide. Examples of low-k dielectric materials include silicon-based low-k materials (e.g., fluorine doped silicon dioxide, carbon-doped silicon oxide, silicon oxycarbides, etc.), polymers, silsesquioxane (SSQ)-based materials (e.g., hydrogen-SSQ, methyl-SSQ, etc.), and so on.

The two conductive structures 629 are over the source region 620A and the drain region 620B, respectively. In some embodiments, the two conductive structures 629 may include a conductive compound, such as titanium nitride. A portion of the polymer structure 601 is wrapped around by two dielectric structures 627 and a conductive structure 629. Another portion of the polymer structure 601 is wrapped around by two other dielectric structures 627 and the other conductive structure 629. The polymer structure 601 may be formed by depositing a polymer. The polymer structure 601 may be used to pattern the source electrode 610A and drain electrode 610B.

In FIG. 6B, the polymer structure 601 is removed, e.g., through etch. The source electrode 610A and drain electrode 610B are formed by depositing a conductive material. The conductive material may be a metal. In some embodiments, the source electrode 610A and drain electrode 610B may be formed in the same metal deposition process. After the source electrode 610A and drain electrode 610B are formed, an electrical insulator 680 is formed, e.g., by depositing an electrical insulating material. The process shown in FIGS. 6A-6B may be part of a FEOL. Frontside or backside metal layers may be formed in a BEOL after the FEOL.

FIGS. 7A-7B are top views of a wafer 2000 and dies 2002, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 8. The wafer 2000 may be composed of semiconductor material and may include one or more dies 2002 having IC devices formed on a surface of the wafer 2000. Each of the dies 2002 may be a repeating unit of a semiconductor product that includes any suitable IC (e.g., ICs with co-metalized electrical contacts as described herein). After the fabrication of the semiconductor product is complete, the wafer 2000 may undergo a singulation process in which each of the dies 2002 is separated from one another to provide discrete “chips” of the semiconductor product. In particular, devices with co-metalized electrical contacts as disclosed herein may take the form of the wafer 2000 (e.g., not singulated) or the form of the die 2002 (e.g., singulated). The die 2002 may include one or more diodes, one or more transistors as well as, optionally, supporting circuitry to route electrical signals to the III-N diodes with n-doped wells and capping layers and III-N transistors, as well as any other IC components. In some embodiments, the wafer 2000 or the die 2002 may implement an electrostatic discharge (ESD) protection device, a radio frequency front-end device, a memory device (e.g., a SRAM device), a logic device (e.g., an AND, OR, NAND, or NOR gate), or any other suitable circuit element. Multiple ones of these devices may be combined on a single die 2002.

FIG. 8 is a side, cross-sectional view of an example IC package 2200 that may include one or more IC devices with co-metalized electrical contacts, according to some embodiments of the disclosure. In some embodiments, the IC package 2200 may be a system-in-package (SiP).

As shown in FIG. 8, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 8 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 8 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

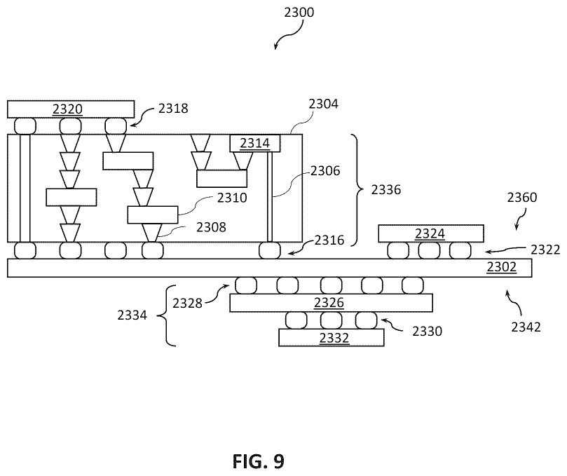

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 8 are solder balls (e.g., for a ball grid array arrangement), but any suitable second-level interconnects 2270 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 9.

The dies 2256 may take the form of any of the embodiments of the die 2002 discussed herein and may include any of the embodiments of an IC device with co-metalized electrical contact. In embodiments in which the IC package 2200 includes multiple dies 2256, the IC package 2200 may be referred to as a multi-chip package. Importantly, even in such embodiments of a multi-chip packaging (MCP) implementation of the IC package 2200, one or more IC devices with co-metalized electrical contacts may be provided in a single chip, in accordance with any of the embodiments described herein. The dies 2256 may include circuitry to perform any desired functionality. For example, one or more of the dies 2256 may be ESD protection dies, including one or more IC devices with co-metalized electrical contacts as described herein, one or more of the dies 2256 may be logic dies (e.g., silicon-based dies), one or more of the dies 2256 may be memory dies (e.g., high bandwidth memory), etc. In some embodiments, any of the dies 2256 may include or otherwise be associated with one or more components with co-metalized electrical contacts, e.g., as discussed above; in some embodiments, at least some of the dies 2256 may not include any III-N diodes with n-doped wells and capping layers.

The IC package 2200 illustrated in FIG. 8 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 8, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 9 is a cross-sectional side view of an IC device assembly 2300 that may include components having one or more IC devices with co-metalized electrical contacts, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices with co-metalized electrical contacts in accordance with any of the embodiments disclosed herein; e.g., any of the IC packages discussed below with reference to the IC device assembly 2300 may take the form of any of the embodiments of the IC package 2200 discussed above with reference to FIG. 8 (e.g., may include one or more components with co-metalized electrical contacts in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 9 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 9), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 7B), an IC device (e.g., the IC device of FIG. 1, 2, 3, 4D, 5C, or 6B), or any other suitable component. In particular, the IC package 2320 may include one or more devices with co-metalized electrical contacts as described herein. Although a single IC package 2320 is shown in FIG. 9, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 9, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other Group III-V and Group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF (radio frequency) devices, power amplifiers, power management devices, antennas, arrays, sensors, and microelectromechanical systems (MEMS) devices may also be formed on the interposer 2304. In some embodiments, the IC devices with co-metalized electrical contacts as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 9 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

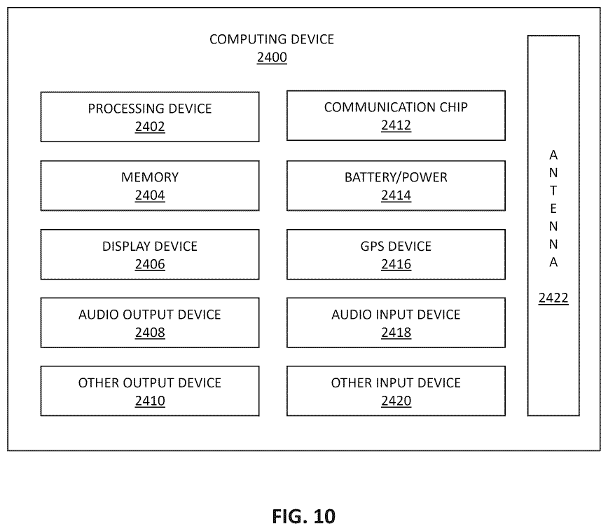

FIG. 10 is a block diagram of an example computing device 2400 that may include one or more components with one or more IC devices with co-metalized electrical contacts, according to some embodiments of the disclosure. For example, any suitable ones of the components of the computing device 2400 may include a die (e.g., the die 2002 of FIG. 7B) including or associated with devices with co-metalized electrical contacts, according to some embodiments of the disclosure. Any of the components of the computing device 2400 may include an IC device with co-metalized electrical contact (e.g., any embodiment of the IC devices described above in conjunction with FIGS. 1-3, 4A-4D, 5A-5C, and 6A-6B) and/or an IC package (e.g., the IC package 2200 of FIG. 8). Any of the components of the computing device 2400 may include an IC device assembly (e.g., the IC device assembly 2300 of FIG. 9).

A number of components are illustrated in FIG. 10 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC (system-on-chip) die.

Additionally, in various embodiments, the computing device 2400 may not include one or more of the components illustrated in FIG. 10, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices with co-metalized electrical contacts as described herein may be particularly advantageous for use as part of ESD circuits protecting power amplifiers, low-noise amplifiers, filters (including arrays of filters and filter banks), switches, or other active components. In some embodiments, IC devices with co-metalized electrical contacts as described herein may be used in PMICs, e.g., as a rectifying diode for large currents. In some embodiments, IC devices with co-metalized electrical contacts as described herein may be used in audio devices and/or in various input/output devices.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include another output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include another input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide various examples of the embodiments disclosed herein.

Example 1 provides an IC device, including a support structure including a semiconductor material, the support structure having a first surface and a second surface opposing the first surface; a semiconductor region of a transistor, in which the semiconductor region is closer to the first surface of the support structure than to the second surface of the support structure; a first conductive structure extending in a direction from the first surface of the support structure to the second surface of the support structure; and a second conductive structure having a first end and a second end, the first end contacting the semiconductor region, the second end contacting the first conductive structure.

Example 2 provides the IC device according to example 1, in which the semiconductor region is a first semiconductor region, the transistor is a first transistor, and the IC device further includes a second semiconductor region of the first transistor; a third semiconductor region of a second transistor; and a third conductive structure having an end contacting the second semiconductor region and another end contacting the third semiconductor region.

Example 3 provides the IC device according to example 2, in which the first conductive structure is between the first semiconductor region and the second semiconductor region.

Example 4 provides the IC device according to example 2 or 3, in which one of the first semiconductor region and the second semiconductor region is a source region of the first transistor, and another one of the first semiconductor region and the second semiconductor region is a drain region of the first transistor.

Example 5 provides the IC device according to any one of examples 1-4, further including a third conductive structure that is closer to the second surface of the support structure than to the first surface of the support structure, in which the first conductive structure is connected to the third conductive structure.

Example 6 provides the IC device according to any one of examples 1-5, in which a portion of the first conductive structure is wrapped around by the support structure.

Example 7 provides the IC device according to any one of examples 1-6, further including a dielectric layer surrounding at least part of the first conductive structure, in which a portion of the second conductive structure is over a portion of the dielectric layer in a first direction and is over another portion of the dielectric layer in a second direction, and the second direction is perpendicular to the first direction.

Example 8 provides an IC device, including a semiconductor region of a first transistor; a semiconductor region of a second transistor; a dielectric structure between the semiconductor region of the first transistor and the semiconductor region of the second transistor; and a conductive structure having a first end and a second end, the first end contacting the semiconductor region of the first transistor, the second end contacting the semiconductor region of the second transistor.

Example 9 provides the IC device according to example 8, further including a gate electrode that is parallel to the dielectric structure, in which the semiconductor region of the second transistor is between the dielectric structure and the gate electrode.

Example 10 provides the IC device according to example 8 or 9, in which the conductive structure includes a portion between the first end and the second end, and the portion contacts the dielectric structure.

Example 11 provides the IC device according to any one of examples 8-10, further including a support structure including a semiconductor material, the support structure having a first surface and a second surface opposing the first surface, in which the semiconductor region of the first transistor or the semiconductor region of the second transistor is closer to the first surface of the support structure than to the second surface of the support structure.

Example 12 provides the IC device according to example 11, in which a portion of the dielectric structure is between the first surface of the support structure and the second surface of the support structure.

Example 13 provides the IC device according to any one of examples 8-12, in which: the semiconductor region of the first transistor is a first semiconductor region of the first transistor, the conductive structure is a first conductive structure, the first transistor further includes a second semiconductor region and a second conductive structure, and the second conductive structure is over the second semiconductor region and is separated from the first conductive structure by an electrical insulator.

Example 14 provides the IC device according to any one of examples 8-13, further including a group of semiconductor structures between the semiconductor region of the first transistor and the semiconductor region of the second transistor, in which a semiconductor structure is a nanoribbon.

Example 15 provides a method of forming an IC device, the method including forming a polymer structure over a first semiconductor region, a second semiconductor region, and a third semiconductor region; removing a first portion of the polymer structure to form a first opening region over the first semiconductor region; removing a second portion of the polymer structure to form a second opening region over the second semiconductor region and the third semiconductor region; forming a first conductive structure in the first opening region; and forming a second conductive structure in the second opening region.

Example 16 provides the method according to example 15, further including before forming the polymer structure, forming a dielectric structure between the second semiconductor region and the third semiconductor region.

Example 17 provides the method according to example 15 or 16, further including before forming the polymer structure, forming a conductive structure between the first semiconductor region and the second semiconductor region.

Example 18 provides the method according to example 17, further including before forming the polymer structure, forming a dielectric layer wrapping around the conductive structure.

Example 19 provides the method according to example 18, further including removing a portion of the dielectric layer to form the first opening region.

Example 20 provides the method according to any one of examples 15-19, in which forming the second conductive structure in the second opening region includes filling the second opening region with a metal, the metal contacting the second semiconductor region and the third semiconductor region.

Example 21 provides an IC package, including the IC device according to any one of examples 1-20; and a further IC component, coupled to the device.

Example 22 provides the IC package according to example 21, where the further IC component includes one of a package substrate, an interposer, or a further IC die.

Example 23 provides the IC package according to example 21 or 22, where the IC device according to any one of examples 1-20 may include, or be a part of, at least one of a memory device, a computing device, a wearable device, a handheld electronic device, and a wireless communications device.

Example 24 provides an electronic device, including a carrier substrate; and one or more of the IC devices according to any one of examples 1-20 and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

Example 34 provides processes for forming the IC device according to any one of claims 1-20.

Example 35 provides processes for forming the IC package according to any one of the claims 21-23.

Example 36 provides processes for forming the electronic device according to any one of the claims 24-33.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a support structure comprising a semiconductor material, the support structure having a first surface and a second surface opposing the first surface;
a semiconductor region of a transistor, wherein the semiconductor region is closer to the first surface of the support structure than to the second surface of the support structure;
a first conductive structure extending in a direction from the first surface of the support structure to the second surface of the support structure; and
a second conductive structure having a first end and a second end, the first end contacting the semiconductor region, the second end contacting the first conductive structure.

2. The IC device according to claim 1, wherein the semiconductor region is a first semiconductor region, the transistor is a first transistor, and the IC device further comprises:
a second semiconductor region of the first transistor;
a third semiconductor region of a second transistor; and
a third conductive structure having an end contacting the second semiconductor region and another end contacting the third semiconductor region.

3. The IC device according to claim 2, wherein the first conductive structure is between the first semiconductor region and the second semiconductor region.

4. The IC device according to claim 2, wherein one of the first semiconductor region and the second semiconductor region is a source region of the first transistor, and another one of the first semiconductor region and the second semiconductor region is a drain region of the first transistor.

5. The IC device according to claim 1, further comprising:
a third conductive structure that is closer to the second surface of the support structure than to the first surface of the support structure,
wherein the first conductive structure is connected to the third conductive structure.

6. The IC device according to claim 1, wherein a portion of the first conductive structure is wrapped around by the support structure.

7. The IC device according to claim 1, further comprising:
a dielectric layer surrounding at least part of the first conductive structure,
wherein a portion of the second conductive structure is over a portion of the dielectric layer in a first direction and is over another portion of the dielectric layer in a second direction, and the second direction is perpendicular to the first direction.

8. An integrated circuit (IC) device, comprising:
a semiconductor region of a first transistor;
a semiconductor region of a second transistor;
a dielectric structure between the semiconductor region of the first transistor and the semiconductor region of the second transistor; and
a conductive structure having a first end and a second end, the first end contacting the semiconductor region of the first transistor, the second end contacting the semiconductor region of the second transistor.

9. The IC device according to claim 8, further comprising:
a gate electrode that is parallel to the dielectric structure,
wherein the semiconductor region of the second transistor is between the dielectric structure and the gate electrode.

10. The IC device according to claim 8, wherein the conductive structure includes a portion between the first end and the second end, and the portion contacts the dielectric structure.

11. The IC device according to claim 8, further comprising:
a support structure comprising a semiconductor material, the support structure having a first surface and a second surface opposing the first surface,
wherein the semiconductor region of the first transistor or the semiconductor region of the second transistor is closer to the first surface of the support structure than to the second surface of the support structure.

12. The IC device according to claim 11, wherein a portion of the dielectric structure is between the first surface of the support structure and the second surface of the support structure.

13. The IC device according to claim 8, wherein:
the semiconductor region of the first transistor is a first semiconductor region of the first transistor,
the conductive structure is a first conductive structure,
the first transistor further includes a second semiconductor region and a second conductive structure, and
the second conductive structure is over the second semiconductor region and is separated from the first conductive structure by an electrical insulator.

14. The IC device according to claim 8, further comprising:
a group of semiconductor structures between the semiconductor region of the first transistor and the semiconductor region of the second transistor,
wherein a semiconductor structure is a nanoribbon.

15. A method of forming an integrated circuit (IC) device, the method comprising:
forming a polymer structure over a first semiconductor region, a second semiconductor region, and a third semiconductor region;
removing a first portion of the polymer structure to form a first opening region over the first semiconductor region;
removing a second portion of the polymer structure to form a second opening region over the second semiconductor region and the third semiconductor region;
forming a first conductive structure in the first opening region; and
forming a second conductive structure in the second opening region.

16. The method according to claim 15, further comprising:
before forming the polymer structure, forming a dielectric structure between the second semiconductor region and the third semiconductor region.

17. The method according to claim 15, further comprising:
before forming the polymer structure, forming a conductive structure between the first semiconductor region and the second semiconductor region.

18. The method according to claim 17, further comprising:
before forming the polymer structure, forming a dielectric layer wrapping around the conductive structure.

19. The method according to claim 18, further comprising:
removing a portion of the dielectric layer to form the first opening region.

20. The method according to claim 15, wherein forming the second conductive structure in the second opening region comprises:
filling the second opening region with a metal, the metal contacting the second semiconductor region and the third semiconductor region.
